(19) United States
(12) Patent Application Publication
(10) Pub. No.: US 2024/0014584 A1
(43) Pub. Date: Jan. 11, 2024

(54) ROBUST LOW PROFILE INTERPOSER

(71) Applicant: Amphenol Corporation, Wallingford, CT (US)

(72) Inventor: Paul R. Taylor, Mechanicsburg, PA (US)

(73) Assignee: Amphenol Corporation, Wallingford, CT (US)

(21) Appl. No.: 18/348,684

(22) Filed: Jul. 7, 2023

Related U.S. Application Data
(60) Provisional application No. 63/388,208, filed on Jul. 11, 2022.

(51) Int. Cl. H01R 12/71; H01R 13/24; H01R 43/20

(52) U.S. Cl. CPC H01R 12/714; H01R 13/2435; H01R 43/205

(57) ABSTRACT

A low profile interposer with multiple electrical contacts held in a housing. Each electrical contact is disposed within a respective opening of the housing. The electrical contact includes a base, a first beam extending from the base to a distal end of the first beam, a second beam extending from the base to a distal end of the second beam. When the electrical contact is in an uncompressed state, a first portion of the distal end of the first beam and a first portion of the distal end of the second beam are positioned between the top surface and the bottom surface; and a second portion of the distal end of the first beam extends above the top surface and a second portion of the distal end of the second beam extends below the bottom surface.

### RELATED APPLICATIONS

This application claims the benefit of U.S. Provisional Application Ser. No. 63/388,208, filed on Jul. 11, 2022, under Attorney Docket No. A1245.70006US00 and entitled “ROBUST LOW PROFILE INTERPOSER,” which is incorporated by reference herein in its entirety.

### BACKGROUND

This patent application relates generally to interconnection systems, such as those including electrical connectors, used to interconnect electronic assemblies.

Electrical connectors are used in many electronic systems. It is generally easier and more cost effective to manufacture a system as separate components that are electrically connected through separable interfaces. With separable interfaces, the components may be separately manufactured and then simply assembled into an overall system. In use, components can be added or replaced in the electronic system, such as to replace a defective component or to enable higher-performing components to be added to the system such that the electronic system is upgraded.

In some instances the components are themselves subassemblies, which are often manufactured by connecting semiconductor devices and other components to a printed circuit board (PCB). The electronic systems may then be assembled by joining the subassemblies. Two-piece connectors are often used for this purpose, with one piece of the connector being mounted on the PCB's of each of two subassemblies to be joined. The subassemblies are joined by mating one piece of the connector with the other.

Components may also be joined through interposers. An interposer has one or more separable interfaces. A separable interface that mates with a component may have a planar array of compliant contacts. A component may be mated to the interposer by pressing the component against the compliant contacts. For example, a semiconductor device, such as a processor chip, may have an array of pads or other conductive structures on a surface. The pads may be aligned with the compliant contacts such that pressing the device against the interposer makes connections between the compliant contacts and the pads or other conductive structures.

Each of the compliant contacts may extend through the interposer to an opposite surface at which a second end of the contact is connected to a second component. In many system architectures, that second component may be a PCB, which may also include an array of pads to which the second ends of the contacts of the interposer are connected. Those connections may be made through compliant contacts on the second ends of the contacts, forming a separable interface. Though, in some interposers, the second end is fixed to a second component, such as via soldering to a PCB.

Interposers may be used in combination with mechanical components that urge one or more components towards separable interface(s) of the interposer. An interposer that connects a semiconductor chip to a PCB, for example, may be used in combination with components that press the semiconductor chip towards a separable interface of the interposer. If the interposer is connected to the PCB through a separable interface, the mechanical components may also press the interposer against the PCB so that the compliant contacts facing the PCB generate sufficient force to make connections to the PCB.

Interposers may be low profile, meaning that they have a low height in a direction perpendicular to the surfaces of the components that are connected through the interposer. Known interposers, for example, may have a height on the order of 1 mm and may contribute to the miniaturization of electronic devices. Interposers, however, may not be made arbitrarily small, as they must simultaneously meet multiple other requirements, such as sufficient mechanical strength, ease of manufacture with sufficient precision, generation of an appropriate contacting force, and contacts in a pattern that aligns with the pads or other conductive structures joined through the interposer.

### SUMMARY

This application describes an interposer and a method of manufacturing an interposer.

In one aspect, concepts described herein may be embodied as an interposer, comprising an insulative housing comprising, a top surface and a bottom surface parallel to the top surface, and a plurality of openings. The plurality of openings are arranged in an array and extending between the top surface and the bottom surface. The interposer further includes a plurality of electrical contacts, each disposed within a respective opening of the plurality of openings. Each electrical contact comprises a U-shaped base, a first beam extending from the U-shaped base to a distal end of the first beam, a second beam extending from the U-shaped base to a distal end of the second beam. For each of the plurality of electrical contacts, when the electrical contact is in an uncompressed state: a first portion of the distal end of the first beam and a first portion of the distal end of the second beam are positioned between the top surface and the bottom surface; and a second portion of the distal end of the first beam extends above the top surface and a second portion of the distal end of the second beam extends below the bottom surface.

Concepts described herein may be embodied as a method of manufacturing an interposer comprising a plurality of electrical contacts held within an insulative member. The insulative member comprises a top surface and a bottom surface parallel to the top surface and comprising a plurality of openings between the top surface and the bottom surface. Each electrical contact comprises a base, a first contact portion extending from the base and a second contact portion extending from the base. The method includes: inserting the plurality of electrical contacts into respective openings in the insulative member such that the base is adjacent a shelf within the respective opening. The method also includes, for each of the plurality of electrical contacts, bending the first contact portion and the second contact portion away from a plane encompassing the base in opposite directions such that a distal end of the first contact portion and a distal end of the second contact portion are separated in a direction perpendicular to the plane. When the electrical contact is inserted at a respective opening of the insulative member, a first portion of the distal end of the first contact portion and a first portion of the distal end of the second contact portion are positioned at a spacing and inside the respective opening between the top surface and the bottom surface of the insulative member when the electrical contact is in an uncompressed state. The method also includes locking the respective electrical contact to the shelf. Locking may include heat staking deforming the insulative member adjacent each of the respective openings to form a protuberance that locks the base of each of the electrical contact in the respective opening between the protuberance and the shelf.

Concepts described herein may be embodied as a method of manufacturing an interposer comprising a plurality of electrical contacts held within an insulative member comprising a top surface and a bottom surface parallel to the top surface. The insulative member comprises a plurality of openings between the top surface and the bottom surface, wherein the plurality of electrical contacts each comprises a base, a first contact portion extending from the base and a second contact portion extending from the base. The method comprises: inserting the plurality of electrical contacts into respective openings in the insulative member. When each electrical contact is inserted into the respective opening, a first portion of a distal end of the first contact portion extends above the top surface and a first portion of a distal end of the second contact portion extends below the bottom surface; the base is adjacent a first shelf within a respective opening; and a second portion of the distal end of the second contact portion is adjacent to a second shelf within the respective opening. The method further includes applying a layer on the top surface of the insulative member to extend over the plurality of openings, wherein the layer includes a plurality of apertures each aligning with the first portion of the distal end of the first contact portion of a respective one of the plurality of electrical contacts to allow the first portion of the distal end of the first contact portion of the respective electrical contact to extend above the layer.

The foregoing features may be used separately or in any suitable combination. The foregoing is a non-limiting summary of the invention, which is defined by the attached claims.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is an exploded view of an illustrative electronic assembly including an interposer disposed between two printed circuit boards, in accordance with some embodiments;

FIG. 2 is a perspective view of a separable interface of an illustrative interpose with an array of electrical contacts in respective openings in a surface of the interposer, in accordance with some embodiments;

FIG. 3A is a plan view of a column with a plurality of electrical contacts stamped from a sheet of conductive metal, in accordance with some embodiments;

FIG. 3B is a plan view of an electrical contact of an interposer with tapered beams, showing multiple regions with different strain when the electrical contact is compressed, in accordance with some embodiments;

FIG. 3C is a side view of an illustrative electrical contact of FIG. 3B with two contact portions bent separately, in accordance with some embodiments;

FIG. 3D is a front view of an electrical contact of FIG. 3B disposed in an opening of a housing of an interposer with two contact portions extending from the housing with tips of the two contact portions bent separately towards the housing, in accordance with some embodiments.

FIG. 4A illustrates a plurality of electrical contacts aligned with respective openings of an illustrative interposer, such as may occur during a step of an illustrative manufacturing process of an interposer in accordance with some embodiments;

FIG. 4B is an enlarged view of a portion of the illustrative interposer of FIG. 4A, in accordance with some embodiments;

FIG. 5A is an isometric view of the illustrative interposer of FIG. 4A with the electrical contacts inserted into respective openings, such as may occur at a later step of the illustrative manufacturing process in accordance with some embodiments;

FIG. 5B is an isometric view of the illustrative interposer of FIG. 5A with the electrical contacts locked into respective openings with heat staking, such as may occur at a later step of the illustrative manufacturing process in accordance with some embodiments;

FIG. 5C is an enlarged view of a void formed from heat staking in the illustrative interposer of FIG. 5B, in accordance with some embodiments;

FIG. 6A is an isometric view of an electrical contact, in accordance with some embodiments;

FIG. 6B is an isometric view of the electrical contact in FIG. 6A inserted into a respective opening of a housing of an interposer, in accordance with some embodiments;

FIG. 6C is a side view of the electrical contact in FIG. 6B sealed inside the respective opening of the housing of the interposer, in accordance with some embodiments.

### DESCRIPTION OF PREFERRED EMBODIMENTS

The inventors have recognized and appreciated techniques that enable simple and reliable manufacture of a very low profile interposer. Techniques as described herein may enable construction of an interposer with a height of less than 1 mm, and less than 0.5 mm in some embodiments. The interposer may nonetheless generate an appropriate amount of contact force that reliable and robust connections may be formed to a component pressed against a separable interface of the interposer. Electrical contacts may be dual compression contacts, such that the interposer may have two separable interfaces on opposing sides of an interposer housing. Further, despite the miniaturized nature of the contacts, the interposer may be resistant to damage at the mating interface(s) as a result of misalignment of components intended to connect to the mating interface or contact from components or other structures that are not intended to be connected to the mating interface.

Techniques as described herein may also enable construction of a robust interposer with a separable interface, or in some implementations two opposing separable interfaces, with contact points separated by less than 0.7 mm in at least one dimension. In some examples, the contact points may be arranged in a rectangular array with separation between two contact points in each of two dimensions of less than 0.7 mm. The arrays of contact points, for example, may be square arrays and the contact points may be spaced on a pitch of approximately 0.65 mm, or less in some examples.

An interposer may be formed by inserting a plurality of electrical contacts into respective openings of a housing. The plurality of electrical contacts may be stamped from a sheet of conductive metal. The contacts may then be formed into a three-dimensional shape and inserted into respective openings of the housing. The electrical contracts may be locked in the openings by heat staking. Features on the electrical contacts may engage with the housing to hold the contacts in place before they are heat staked. These features, for example, may provide a more precise positioning of the contact points of the array of contact points, enabling the pads of a component in contact with the separable interface to be smaller, while ensuring reliable connections through the interposer.

Electrical contacts inserted into the opening of the housing may be captured within the housing. In some examples the contacts may be captured via heat staking. In other examples, the contacts may be captured by applying a film to one or more surfaces of the interposer housing, with openings to allow portions of the contacts to extend through the film to provide a mating interface for making connections to a component pressed against the interposer.

Heat staking may capture a base of each electrical contact within an opening in the interposer housing. Compliant portions of the contact may be free to move within the opening. Such a structure may enable deflection of the electrical contact over a large percentage of the length of the contact and/or may enable spring energy to be stored in the base of the contact when the contact is compressed. As a result, the electrical contacts may generate a desired amount of contact force, even if shorter than an electrical contact in which the base of the electrical contact is embedded in a housing of the interposer.

In some examples, heat staking may result in asymmetrical protuberances locking an electrical contact into the interposer housing. For example, a protuberance may be formed on only one side of the electrical contact. For a dual compression contact, such an asymmetrical locking arrangement may enable the contact to rotate during compression, if the forces on each side of the contact are unbalanced. Such rotation may tend to equalize the forces generated by the two beams of the dual compression contact, equalizing the contact force at each of two separable interfaces of the interposer.

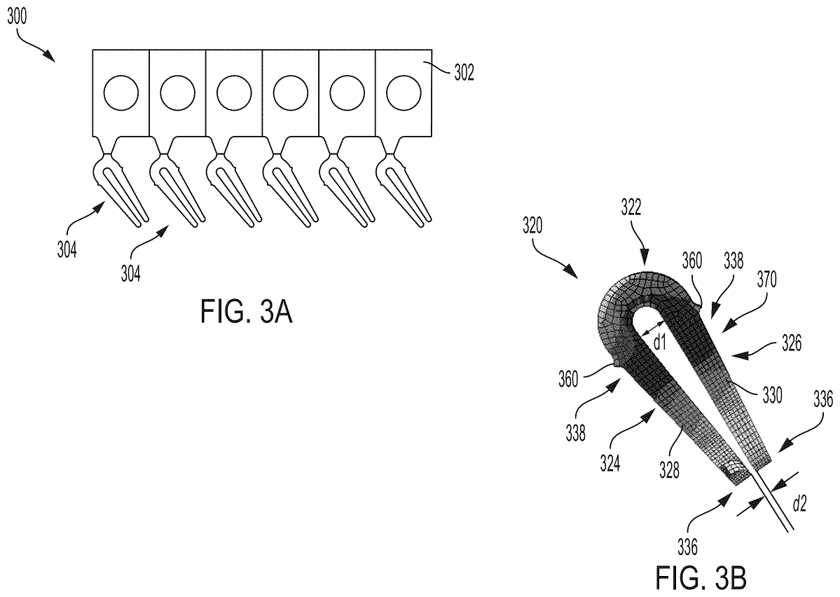

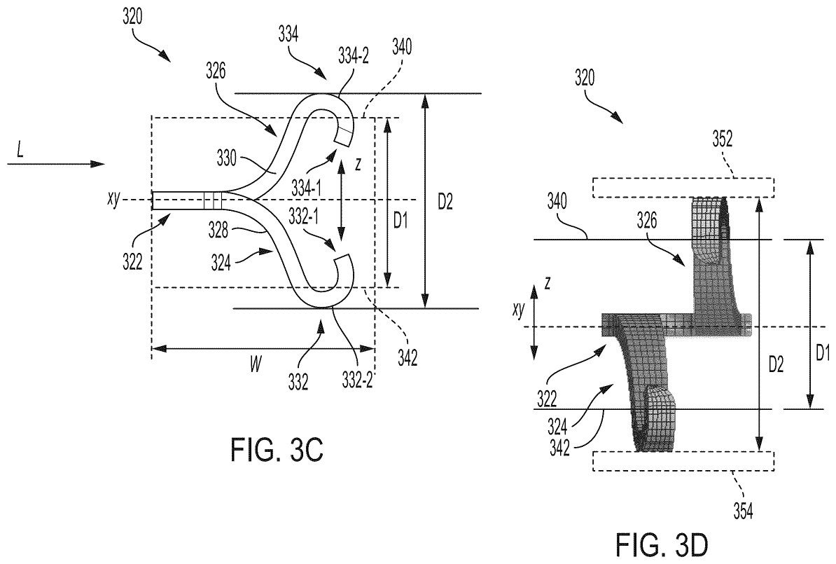

In some embodiments of a dual compression contact, each of the electrical contacts of an interposer may have a U-shaped base and two contact portions each extending from the U-shaped base. For example, FIGS. 3B and 3C illustrate an electrical contact having a U-shaped base extending in a plane, and two beams that extend from the U-shaped base and away from the plane so that the distal ends of the beams are separated. Once the electrical contacts are formed, they may be inserted into respective openings of the interposer to each rest on a shelf in the inner wall of the respective openings. For each electrical contact, heat staking may be used to form a protuberance on top of the electrical contact base to lock the electrical contact in place. The protuberance may be formed, for example, with a heated punch that presses on a thermoplastic housing over an edge of the inner wall of the respective opening near the base of the electrical contact.

U-shaped contacts may be manufactured in the shape illustrated in FIGS. 3B and 3C by stamping the U-shaped portion from a sheet of metal. Such an approach may enable a tight radius on the U-shaped portion of the contact. Two contact portions of each of the electrical contacts may be formed to extend from the U-shaped portion and away from the plane of the sheet of conductive metal so that the distal ends of the contact portions are separated. Each of the electrical contacts may have an engagement feature. For example, the base of an electrical contact may include one or more projections. A projection may be an extension extending perpendicularly from the centerline of the electrical contact such that, when the electrical contact is inserted in a respective opening of the housing of the interposer, at least the extension(s) of the base rest on respective shelves in corresponding grooves in the inner wall of the respective opening and engage with the corresponding groove(s). The extension(s) may further engage with the corresponding grooves so that the electrical contact temporarily stays in the respective opening after being inserted therein. Heat staking may be used to form a protuberance on top of each of at least the extension portion of the base, so that the base is captured between the shelf and the protuberance and the electrical contact is locked in place.

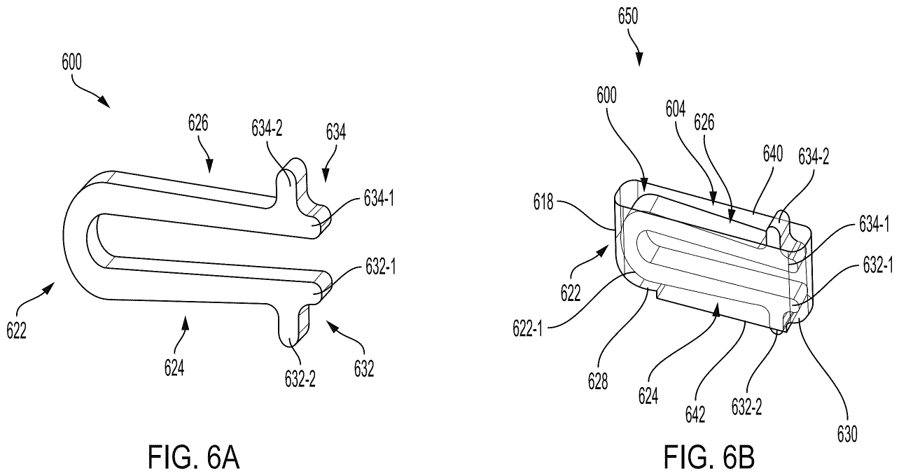

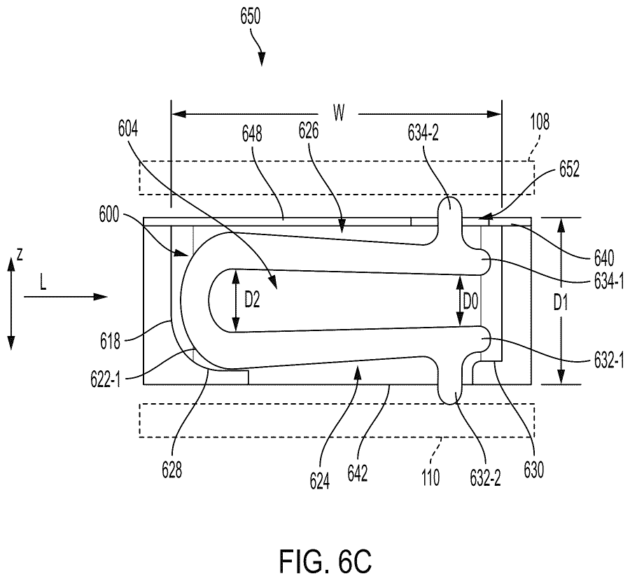

In some embodiments, each of the electrical contacts of an interposer may have a base and two contact portions each extending from the base. For example, FIGS. 6A and 6C illustrate an electrical contact having a U-shaped base and two beams that extend from the U-shaped base. In this example, the U-shaped based and the two beams extending from the U-shaped base are disposed within a plane, such as may result from stamping the contact from a sheet of metal. Once the electrical contacts are formed, they may be inserted into respective openings of the interposer. In the example in FIGS. 6A and 6C, the contacts may be loaded into the housing with this plane perpendicular to the top and bottom of the interposer housing. The contacts, for example, may be inserted through a top surface of the interposer housing. The base and the distal tip of one of the beams for each of the contacts may rest on shelves extending from the inner wall of the respective openings. These shelves may be adjacent the bottom surface of the interposer housing.

When inserted into a respective opening of the housing, each electrical contact may have portions of distal ends of the two beams inside the opening when the electrical contact is in an uncompressed state. Following insertion of the electrical contacts into respective openings, a layer may be applied to the top surface of the housing to extend over the respective openings to seal the electrical contacts therein. The layer may have a plurality of apertures each aligned with a respective opening to enable a portion of the distal end of the electrical contact in the respective opening to extend through the openings and above the top surface to be in contact with a respective substrate to be connected to the interposer. The layer may be a film such as a plastic film, in some embodiments. For example, the film may be a polyimide film such as KAPTON.

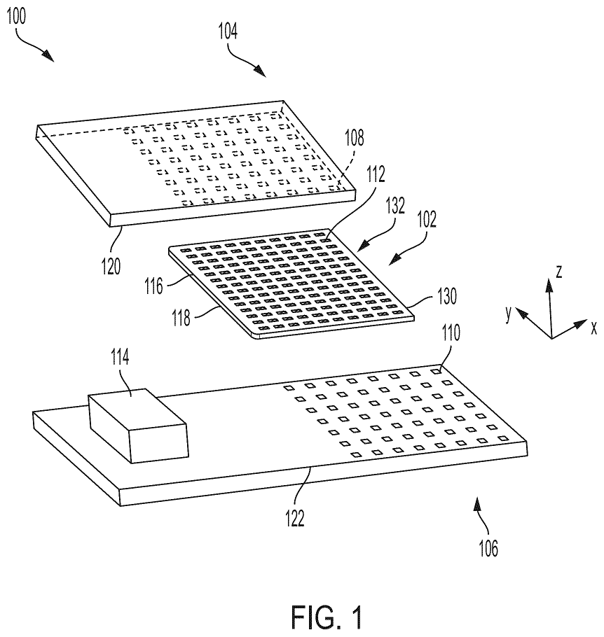

FIG. 1 is an exploded view of an illustrative electronic assembly including an interposer disposed in between two components, which in this example are illustrated as two printed circuit boards. Here, electronic assembly 100 is shown with substrates 104 and 106, an interposer 102 between the substrates and semiconductor devices and other components attached to the substrates, of which component 114 is an example. Substrates 104 and 106 may be part of respective electronic components, implemented in this example as subassemblies including other electronic components. For example, substrate 106 may be a motherboard and substrate 104 may be a daughter card (e.g., a processor card).

In the example of FIG. 1, electronic assembly 100 is shown to have a mezzanine or stacking configuration, such that the electrical interface of substrate 106 is in a plane parallel to the plane of the electrical interface of substrate 104. In the example of FIG. 1, substrate 104 includes pads 108 formed on the bottom surface 120 of substrate 104, and substrate 106 includes pads 110 formed on the top surface 122 of substrate 106, where the bottom surface of substrate 104 is parallel to the top surface of substrate 106. The pads of each of the substrates 104, 106 may be connected via traces or other conducting structures within the substrates to semiconductor chips, such as electronic component 114, or other components mounted on the substrates.

In this example, the pads of the electrical interfaces on both substrate 104 and substrate 106 have a similar configuration, each with an array of pads. The pads within each array may be closely spaced, leading to miniaturization of electronic assembly 100. An interposer as described herein enables the pads to be spaced, center to center, by less than 1 mm in at least one dimension. The pads, for example, may be arranged in an array with multiple parallel columns of pads. The pads within a column may have a center to center spacing of less than 1 mm, or less than 0.7 mm or between 0.4 and 0.7 mm, such as about 0.65 mm, in some examples. The columns may have a center to center spacing of less than 1 mm, or less than 0.7 mm or between 0.4 and 0.7 mm, such as about 0.65 mm, in some examples. In this example, the array of pads is a square array.

During operation, pads 108 are in electrical contact with pads 110 via interposer 102. In this example, interposer 102 has dual compression contacts, with contact portions of each contact making contact with a pad 108 on the bottom surface 120 of substrate 104 a pad 110 on the top surface 122 of substrate 106. Force to press the contact portions against the corresponding pads is generated by mechanical components of electronic system 100 (not shown in FIG. 1, pressing substrates 104 and 106 together, with interposer 102 between them.

The separation between the substrates, and consequently the height of interposer 102 (along the z-axis), may be small. A small separation may enable high signal speeds between the PCB's and also reduced packaging. The separation, for example, may be 1 mm or less, or less than 0.8 mm, or less than 0.6 mm, or between 0.4 and 0.6 mm, such as approximately 0.5 mm, for example.

With further reference to FIG. 1, the interposer 102 may include a housing 130, a top surface 116, a bottom surface 118 parallel to the top surface, a plurality of openings 132 through the housing 130, and a plurality of electrical contacts 112 in respective openings. The plurality of openings may be arranged in an array and extending between the top surface 116 and the bottom surface 118 of the housing 130. In some embodiments, the housing may be an insulative member, and the plurality of electrical contacts may be made of conductive metal, such as a copper alloy. Phosphor bronze, for example, may be used.

Interposer 102 may be mounted to a substrate, which may be substrate 106 in this example, via mechanical components (not shown). The mechanical components force contact portions of the electrical contacts against the pads 110 on substrate 106. The contact portions may be compliant, such as compliant beams at the bottom side 118 of interposer 102. When interposer 102 is pressed against substrate 106, those beams may be deflected, resulting in spring-loaded contacts. Latching structures (not shown in FIG. 1) may retain interposer 102 in place on substrate 106, generating the force that creates the spring-loaded contacts. Further, substrate 104 may be pressed into the top surface 116 of interposer 102. Interposer 102 or some other components of electronic assembly 100 may include latching structures (not shown in FIG. 1) designed to hold substrate 104 to the interposer and to press the substrate against the contact portions of the interposer contacts. In some embodiments, the upper contact portions of the contacts of the interposer 102 may be compliant and may exert a force against pads 108 when substrate 104 is pressed against the interposer. Similarly, the lower contact portions of the contacts of the interposer 102 may be compliant and may exert a force against pads 110 when substrate 106 is pressed against the interposer.

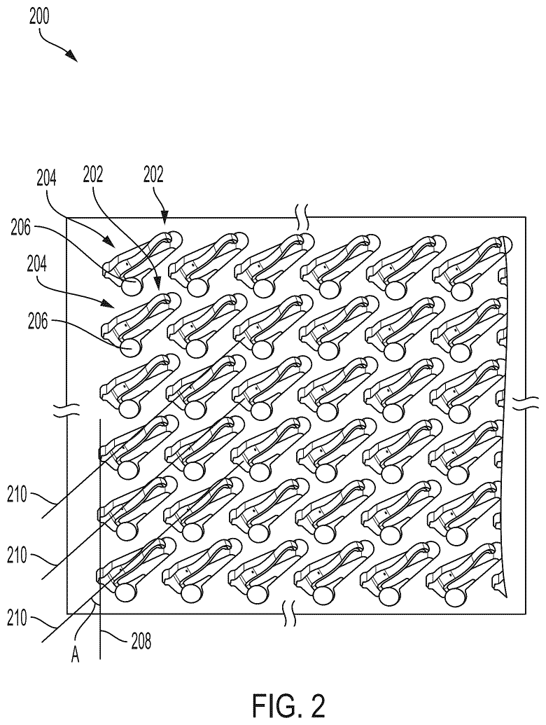

FIG. 2 illustrates an array of electrical contacts in respective openings in an illustrative interposer, in accordance with some embodiments. In some embodiment, interposer 200 may be at least a portion of the interposer 102 shown in FIG. 1, having a plurality of electrical contacts 202 disposed within respective openings of the plurality of openings 204 of a housing of interposer 200. The electrical contacts 202 may be locked into respective openings 204 by protuberances 206. Protuberances 206 may be formed by deforming a portion of the housing of the interposer, which is further described in detail.

In this example, the electrical contacts are arranged in a plurality of parallel columns extending in a column direction 208. Each of the electrical contacts has two beams, both of which are elongated, providing an elongated axis 210 to the contact. In this example, the elongated axes 210 of the contacts are parallel to each other. The elongated axes may make an acute angle, A, with respect the column direction 208. The angle A may be, for example, between 25 degrees and 55 degrees, such as between 30 and 40 degrees or about 35 degrees in some examples. An acute angle may enable the contacts to have compliant beams that generate a desired contacting force while making contact with a tightly packed array of pads on substrates above and below interposer 200.

FIG. 3A is a plan view of a plurality of electrical contacts stamped from a sheet of conductive metal, in accordance with some embodiments. A plurality of electrical contacts 304 may be stamped from a sheet of conductive metal to create a blank 300. Blank 300 may be worked to form contacts with a three-dimensional structure.

FIG. 3B is a plan view of an electrical contact of an interposer. Electrical contact 320 may be any of the plurality of electrical contacts 304 in FIG. 3A. In some embodiments, the electrical contact 320 may be any of the electrical contacts 202 (FIG. 2). The electrical contact 320 may include a base 322 and a first contact portion 324 and a second contact portion 326. The base 322 may be a U-shaped base, which may be stamped from the sheet of conductive metal as described above. Each of the contact portions 324, 326 may include a beam extending from the base 322. For example, contact portion 324 may include beam 328, and contact portion 326 may include beam 330, where beams 328, 330 both extend from the base 322. In the examples of FIGS. 3A and 3B, the base and the beams are integral for each of the electrical contacts. This configuration may result from stamping the contacts from a sheet of conductive metal.

As shown in FIG. 3C, which is a side view of an illustrative electrical contact of FIG. 3B, the contact portions 324, 326 may be bent in opposite directions away from a plane encompassing the base 322 (e.g., plane xy). In such configuration, a distal end 332 of the first contact portion 324 and a distal end 334 of the second contact portion 326 are separated in a direction z perpendicular to the plane (e.g., plane xy). The bending of the contact portions 324, 326 enables contact surfaces 332-2 and 334-2 to be separated by a distance D2. The distance D2 may be greater than the height D1 of a housing of the interposer such that the distal ends of the contact portions to extend respectively through the top and bottom surfaces (e.g., 340, 342) of the housing in which the electrical contract is disposed, in an uncompressed state when the electrical contact is properly installed in the opening of the housing. When the interposer is used, the contact surfaces 332-2 and 334-2 may be in electrical contact with the pads of the substrates that are pressed against the top and bottom surfaces of the interposer (see FIG. 1).

In some embodiments, tips of the distal ends 332-1, 334-1 of the contact portions 324 and 326 may be protected within an opening in the insulative housing of the interposer. In the example of FIGS. 3C and 3D, this configuration is achieved by bending the distal ends 332-1 and 334-1 to curve back towards the xy plane.

Returning to FIG. 3B, in some embodiments, the contact portions 324, 328 may each be tapered. For example, the width of the contact portions near the distal ends 336 may be narrower than the width of the contact portions at proximate ends 338 near the base 322. This configuration enables the electrical contact to store the spring energy more efficiently. For example, when the electrical contact is in electrical contact with a substrate (e.g., 104, 106 of FIG. 1), the tapered beams are pressed down into the interposer. The spring energy stored in the tapered beams will provide better spring force and thus better contact with the substrate(s).

Additionally and/or alternatively, distal ends 336 of the contact portions 324, 326 may be positioned at a closer distance than the proximate ends 338 are positioned. As shown in FIG. 3B, the distance between the distal ends (d2) is smaller than the distance between proximate ends (d1). Having the distal ends of the contact portions of the electrical contacts close enough will enable the pads (e.g., 108, 110 in FIG. 1) in the substrates above and below the electrical contact to be aligned when viewed from a side. For example, as shown in FIG. 3D, in which a pad 352 in the top substrate and a pad 354 in the bottom substrate are aligned perpendicularly to the plane xy that encompasses the base 322. The pads 352, 354 may each be formed on two mating substrates (e.g., PCB boards). Thus, having the distal ends of the contact portions of the electrical contacts closer may enable the pads for the substrates to be connected by the interposer to be aligned in the direction z. Such alignment may simplify design of the interposer and/or may improve high frequency performance of the interposer. The distance between distal ends d2 (see FIG. 3B) may be sufficiently large that the distal ends do not touch each other when the electric contact is compressed between substrates. The configuration shown in FIGS. 3A-3D also result in less metal in each contact portion than conventional interposers such that a lower impedance can be achieved.

Returning to FIG. 3B, additionally, and/or alternatively, the base 322 of the electrical contact 320 may have one or more barbs 360 near the proximate ends 338 of the contact portions (e.g., two barbs with one on each side of the base). The barb(s) 360 may be formed during stamping a sheet of conductive metal to form blank 300 (FIG. 3A). Barbs 360 may result from a feature of a stamping die or may result from progressive die cuts, with barbs 360 formed at the intersection of progressive die cuts. The barb(s) 360 may have sharp tips that bite into the inner wall of the opening in which the electrical contact is inserted with an assembly tool so that the electrical contact stays in the opening when the assembly tool is withdrawn, before heat staking is performed.

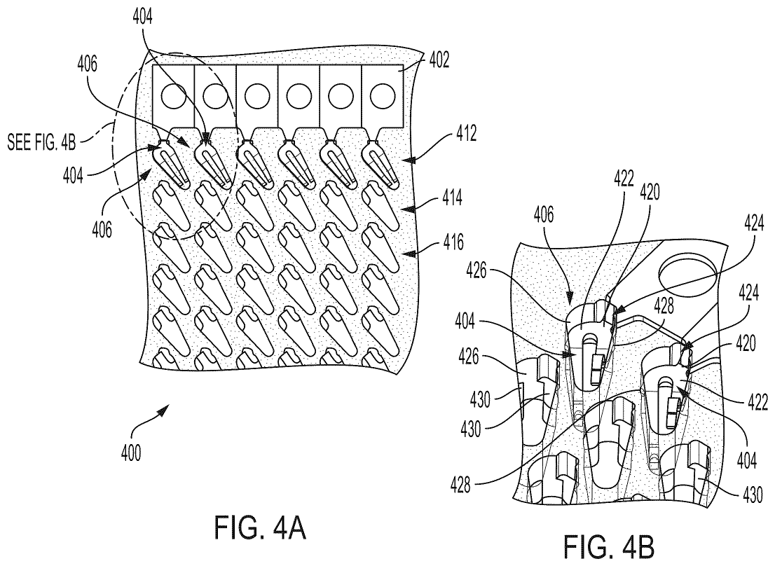

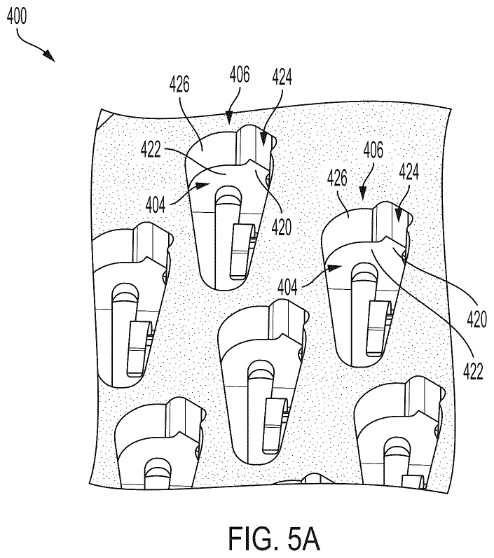

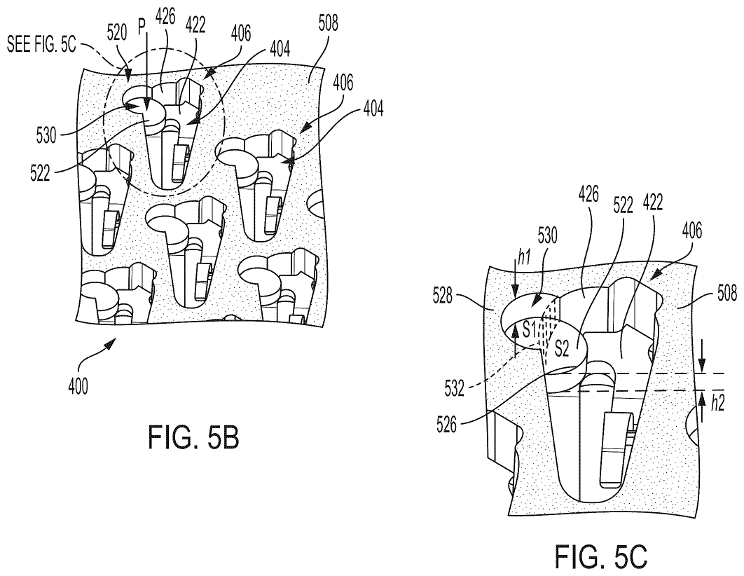

FIGS. 4A, 4B, 5A and 5B illustrate a sequence of steps of an illustrative manufacturing process for an interposer. In this example, the interposer is formed by securing multiple electrical contacts as described above in connection with FIGS. 3A-3D within respective openings in a housing. A plurality of electrical contacts 404 may be stamped for a sheet of conductive metal, in a similar manner as shown in FIG. 3A. The electrical contacts 404 may be manufactured by forming the contacts in blank 300 into three-dimensional shapes with contact portions as described in connection with FIGS. 3C and 3D.

FIG. 4A illustrates a plurality of electrical contacts aligned with respective openings of an illustrative interposer 400 in a stage of an example manufacturing process. The electrical contacts 404 may be held on a carrier. In the example in FIG. 4A, the carrier is a support strip 402 having a plurality of sections spaced in the same spacing of the plurality of openings 406 of the housing of an interposer. Thus, the plurality of electrical contacts 404 may be aligned altogether with a group of openings (e.g., rows 412, 414, 416) of the housing of the interposer with the use of the support strip 402. In the configuration shown in FIG. 4A, the U-shape in the base of each of the electrical contacts, combined with the acute angle as described above, results in a tight spacing (small pitch) among the plurality of electrical contacts in the housing of the interposer.

As shown in FIGS. 4A-4B, each of the plurality of electrical contacts 404 may be connected to the strip support 402 via respective extensions 420, where each extension 420 may extend from the base of a respective electrical contact connecting to a corresponding section of the strip support 402. In some examples, before the electrical contacts are inserted into respective openings of the housing, the electrical contacts connecting to the support strip 402 may be severed therefrom at the extensions of respective bases of the electrical contacts to enable the electrical contacts to be inserted into respective openings of the housing. In other examples, the electrical contacts may be severed from the support strip 402 as they are being inserted into respective openings of the housing.

FIG. 4B illustrates that the housing of the interposer may have shelves 430 within the openings of the housing. An electrical contact may be pressed by a tool into the opening of the housing until it seats on one or more shelves 430 within the opening. The tool may have an edge in a location where the electrical contact is to be separated from support strip 402. In this example, that location is at the end of extension 420. As can be seen in FIG. 4B, which shows support strip 402 with electrical contacts attached, when the contacts are inserted to the desired depth in the openings, the housing interferes with the support strip 402, which is prevented from staying in the same plane as the electrical contacts as the contacts are pressed into the opening. As a result, force of the tool severs the electrical contacts from the support strip 402. Thereafter, the support strip 402 may be removed. Such an operation enables multiple electrical contacts to be inserted into the interposer housing in one cycle of an assembly tool, which may provide efficient assembly of an interposer.

Regardless of how the electrical contact is severed from the support strip, when an electrical contact is severed from the support strip, an extension (e.g., 420) may be formed. When the electrical contact is severed from the support strip, the extension 420 remains extending from the base of the electrical contact. As such, for each of the plurality of electrical contacts, the extension is also integral with other parts of the electrical contract (e.g., the base, the contact portions etc. in FIG. 3B).

The electrical contacts 404, severed from their support strip, are seated within respective openings (e.g., 406). For example, the base 422 of an electrical contact 404 may be pressed against a shelf (such as 430) in the inner wall 426 of the respective opening. The shelf 430 in the inner wall 426 may be integrated with the inner wall in some embodiments. For example, the housing may be molded with the plurality of openings and a respective shelf (or multiple shelves) in the inner wall of each opening. In the configuration shown, each opening 406 of the housing may be bounded by a surface, e.g., inner wall 426, where the inner wall 426 may have a curved segment. The base of the electrical contact 422 may be of a curved edge (e.g., a U-shape) to follow the curved segment of the inner wall of the opening. As shown in FIG. 4B, the extensions 420 may each be engaged with a respective groove 424 of each of the openings in the manner as described above. Extensions may restrain rotation of an electrical contact within an opening.

FIG. 5A is an isometric view of a portion of an illustrative interposer 400 with the electrical contacts inserted into respective openings, in accordance with some embodiments. The illustrative interposer 400 may be implemented as at least a portion of the interposer 102 shown in FIG. 1, in some examples. Interposer 400 may represent a portion of the interposer shown in FIGS. 4A and 4B at a later stage of manufacture. In this example, electrical contacts have been inserted into multiple columns of openings in a housing of the interposer.

As shown in FIG. 5A, a plurality of electrical contacts 404 may have been inserted into respective openings 406 of the housing of the interposer. As shown, each opening 406 of the housing may be bounded by a surface, e.g., inner wall 426. When pressed into a respective opening (e.g., 406), the base 422 of an electrical contact 404 may be pressed against a shelf (such as 430 in FIG. 4B) in the inner wall 426 of the respective opening. Thus, the shelf is underneath the base of the electrical contact and not visible in FIG. 5A. The shelf in the inner wall may be integrated with the inner wall in some embodiments. For example, the housing may be molded with the plurality of openings and a respective shelf (or multiple shelves) in the inner wall of each opening. In some embodiments, the inner wall 426 of each opening may have a curved segment. The base of the electrical contact 422 may be of a curved edge (e.g., a U-shape) to follow the curved segment of the inner wall of the opening.

With further reference to FIG. 5A, each of the electrical contacts 404 may have an engagement feature, which may include, for example, one or more projections that extends from the base 422. Projections may aid in positioning the electrical contact in the housing at one or more phases of manufacture and/or use of the interposer. A projection, such as extension 420, may extend into and engage with an inner wall 426 of the opening 406. For example, the extension 420 may engage with a groove 424 in the inner wall 426. Such a projection may position the electrical contact with respect to the opening and/or may restrain rotation of the electrical contact in use.

Additionally, and/or alternatively, a projection may have other shapes, such as a tab or a barb, and may serve other functions. For example, one or more barbs (see 428 in FIG. 4B, and 360 in FIG. 3B) may have sharp tips that bite into the inner wall 426 of the opening in which the electrical contact is inserted with an assembly tool so that the electrical contact stays in the opening when the assembly tool is withdrawn, before heat staking is performed.

During manufacture, for example, a projection may retain the electrical contact in an opening in the interposer housing. As shown in FIG. 4B, the base 422 of each electrical contact is connected to the support strip 402. An assembly tool may press the electrical contact into a respective opening of the interposer 400, at which time the electrical contacts may have been severed from a support strip. Having the projection of the electrical contact engage with an inner wall of the housing may hold the electrical contact in the opening when the assembly tool is withdrawn. Projections in the form of one or more barbs, such as barbs 428 (or 360 in FIG. 3B) described above, may serve this function. Alternatively or additionally, an extension such as extension 420 may also serve this function. The size of the groove (e.g., a width) may be slightly smaller than the size of the extension (e.g., a width) such that, when the electrical contact is inserted into a respective opening, the extension frictionally engages with the groove in the wall of the opening. This engagement holds the electrical contact in the opening, even when the assembly tool is withdrawn, which might otherwise pull the electrical contact out of the opening.

Once the electrical contacts are inserted into respective openings of the housing of the interposer, the electrical contacts may be locked in place by deforming portions of the housing adjacent the electrical contracts. In some embodiments, the housing may be deformed by heat staking. FIG. 5B is an isometric view of the illustrative interposer 400 of FIGS. 5A and 4A-4B with the electrical contacts locked into respective openings with heat staking, such as may occur at a later step of the illustrative manufacturing process in accordance with some embodiments. Heat staking may be performed by applying energy to a portion 520 of the housing 508 of the interposer 400 and deforming the portion of the housing to form a protuberance 522 over the base. For each of the electrical contacts, the respective portion 520 may be adjacent an edge of the respective opening 406 in which the electrical contact is inserted and adjacent the base 422 of the electrical contact 404. The deforming may cause a portion of the housing material to be displaced over the base and lock the electrical contact in the opening.

In some embodiments, the energy may be applied as heat to increase the temperature of portion 520 of the housing adjacent the base. Energy may be applied in other forms, however, such as ultrasonic energy. In implementations in which the housing is made of a thermoplastic material, applying heat may place the portion of the housing in a molten or softened state. In combination with applying heat, pressure may be applied to portion 520 to push material from the housing into a protuberance 522. In some examples, the pushing and the heating may be supplied by the same manufacturing tool, such as a heated punch (not shown). The motion and/or the heat supplied by the punch may be controlled to cause material from the housing to move down to form the protuberance 522, without disrupting the position of the electrical contact. In some embodiments, punching may entail moving a tip of the punch in the same direction as the inner wall 426 (e.g., in a vertical direction P) such that the protuberance 522 becomes a horizontally extending segment. In an example, the direction P may be parallel to the direction z of the electrical contact (see FIGS. 1, and 3C-3D). The punch may have a tip shaped to match the desired shape of the protuberance. Once the heat punch is removed, the deformed portion of the housing from heat staking may solidify to a new shape. In the example illustrated, the tip of the punch may be circular, which may result in the circular protrusion illustrated in FIGS. 5B-5C.

When the electrical contacts are locked into placed by deforming portions of the housing adjacent openings, for each such opening, a void may be created in the housing near the base of the electrical contact, representing the location from which material moved down to the top of the electrical contact 422. As shown in FIG. 5B, void 530 may be formed above the protuberance 522. An enlarged view of the void 530 is shown in FIG. 5C. The void may be defined between the top surface 526 of the protuberance 522 and top surface 528 of the housing 508, and beyond a portion 532 of the inner wall 426 of the opening 406. The portion 532 is part of a continuous surface along the inner wall 426 before the void is created. During heat staking, for example, the housing material in the portion where the void will be formed is pushed down to form the protuberance 522. Thus, the volume of the void may equal the volume of a portion of the protuberance inside the inner wall of the opening.

FIG. 5C illustrates an example interposer resulting from use of a punch when the cross-section of the punch used for heat staking is circular. As a result, the void 530 may be a partial cylindrical shape. The protuberance may have a partial disk shape, for example. In this example, the volume of the void is calculated as the area S1 multiplied by the depth of the void h1; the volume of the protuberance inside the inner wall is calculated as the area S2 multiplied by the thickness of the protuberance h2. Although the void is shown to be a partial cylindrical shape, the void can be of any other shape depending on the cross-section of the punch used for heat staking. Further, the protuberance may have any suitable shape.

Returning to FIG. 5B, once an electrical contact is inserted and locked into place in a respective opening of the housing, the base 422 of the electrical contact 404 is captured between a shelf (such as 430, in FIG. 4B) and the protuberance 522. Although it is shown that the protuberance is formed at a different stage of the manufacturing process, the protuberance and the shelf within each of the plurality of openings may be monolithic and integral because both the protuberance and the shelf may be formed from the same materials of the housing.

In one or more manufacturing steps described in FIGS. 4A-4B and 5A-5C, the electrical contacts as described in FIGS. 3A-3D may be inserted and locked into respective openings of the housing 400. For example, the shelf in each of the openings of the housing may be parallel to the top and bottom surfaces of the housing to enable the base of a respective electrical contact in each opening to be disposed parallel to the top and bottom surfaces as well. That is, the plane that encompasses the base of the electrical contact (e.g., plane xy in FIG. 3C) may be positioned in parallel to and between the top surface and bottom surface of the housing of the interposer (e.g., surfaces 116, 118 of the housing 130 in FIG. 1). The first and second contact portions of each electrical contact may extend from the base of the electrical contact towards the top and bottom surfaces of the housing, respectively (shown in FIG. 3C). When an electrical contact is in an uncompressed state, the contact portions of the electrical contact will extend through the top and bottom surfaces of the housing and outside the housing (shown in FIG. 3C). This enables the electrical contact in the interposer to be in contact with the pads formed on the substrates that are pressed against the surfaces of the interposer. For example, with reference to FIG. 1, when in operation, the electrical contacts (112) of the interposer are in electrical contact with pads 108 of substrate 104 and/or pads 110 of substrate 106.

Such a configuration may sufficiently lock the electrical contacts in place such that, when the interposer is pressed between two substrates the contact portions deflect and exert a counter force based on spring energy stored in the contact portions. The electrical contact of FIG. 3B is shaded to show relative stress, and therefore spring energy, stored in an electrical contact when compressed. In this example, region 370 has the highest relative stress, with successive regions towards the base towards the tips having successively lower stress. Nonetheless, the U-shaped electrical contact enables storage of spring energy along substantial portions of the length of the electrical contact, leading to an appropriate contact force, even for a relatively small contact.

In the configuration of FIG. 5C, the base of the electrical contact is captured via a protuberance on one side, enabling the other side of the base to pivot within the opening if there is an imbalance of forces on the contact. Enabling such a motion may provide more reliable connections through the interposer. For example, an interposer with two opposing separable interfaces may have dual compression contacts with two beams extending from the base. An imbalance of forces may result from any of a number of causes, such as imprecision in the position of the contact points of each of the beams relative to the center of the interposer or imprecision in the location of the pads of the components mating to either or both of the separable interfaces. Such an imbalance may result in the contact force at one beam of the electrical contact being higher than at the other, which may lead to an unreliable connection at one or both of the interfaces. By enabling the contact to pivot in response to the imbalance, the imbalance may be reduced, reducing the chances of an unreliable connection.

Electrical contacts of other shapes and configurations may be used to achieve a robust low-profile interposer. FIGS. 6A-6C show various views of an electrical contact 600, in accordance with some embodiments, with a different shape than described in connection with FIGS. 2-5C. Nonetheless, as with the embodiment of FIGS. 2-5C, each contact as illustrated in FIG. 6A may have one or more beams with a portion of the distal end of the beam between the top and bottom surfaces of the interposer housing. That first portion of the distal end may be the distal tip such that the distal tip is protected from damaged from unintended contact with the mating interface of the interposer. A second portion of the distal end of each of the beams may contain a contact surface extending above an exterior surface of the interposer, here shown as two beams each with a portion extending above the top surface and below the bottom surface, respectively. In the embodiment of FIGS. 2-5C these first and second portions are formed by bending the distal end of two beams, which have broadsides generally parallel to the top and bottom surfaces such that they may be formed into the illustrated shape. In the embodiment of FIG. 6A, the contact may be stamped from a sheet of metal such that the first and second portions of the distal end are formed when the contact is stamped. In this example, the second portion is formed as part of a projection from the distal end of the beam.

FIG. 6A is an isometric view of the electrical contact 600. FIG. 6B is an isometric view of the electrical contact in FIG. 6A inserted into a respective opening of a housing of an interposer, in accordance with some embodiments, with a different opening of described in connection with FIGS. 2-5C. FIG. 6C is a side view of the electrical contact in FIG. 6B sealed inside the respective opening of the housing of the interposer, in accordance with some embodiments.

In some embodiments, the electrical contact 600 may have components corresponding to the components described above for the electrical contact shown in FIGS. 3A-3D (comparing 600 to 304 in FIG. 3A and 320 in FIG. 3B). Accordingly, features described in connection with FIGS. 2-5C may similarly apply with respect to the connector illustrated in connection with the contacts, and interposers containing them, as shown in FIGS. 6A-6C. For example, FIGS. 6A-6C illustrate a single contact, but it should be appreciated that an interposer may be formed of an array of such contacts, as described elsewhere herein, and that such interposers may be used also as described.

The distal ends of the electrical contacts shown in FIGS. 6A-6C are, however, shaped differently than those shown in FIGS. 2-5C (comparing 632, 634 to 332, 334 in FIG. 3C). Further, the contact portions in the configuration in FIG. 6A are straight rather than bent (comparing 624, 626 to 324, 326 in FIG. 3C).

As shown in this example, electrical contact 600 may include a U-shaped base 622, a first contact portion 624 and a second contact portion 626 each extending from the U-shaped base to a respective distal end 632, 634. Similar to electrical contact shown in FIGS. 3A-3D, the U-shaped base 622, the first contact portion 632 and the second contact portion 634 are integral for each electrical contact. This configuration may result from stamping the contact(s) from a sheet of conductive metal.

With further reference to FIG. 6A, each of the contact portions 624, 626 may be a beam, which also may be tapered. Additionally and/or alternatively, distal ends 632, 634 of the contact portions 624, 626 may be positioned at a closer distance (shown as DO in FIG. 6C) than the distance between proximate ends of the contact portions (shown as D2 in FIG. 6C). The distal end of each contact portion may include two portions. For example, distal end 634 may include a first portion 634-1 and a second portion 634-2 each extending in a perpendicular direction from each other. Similarly, distal end 632 may include a first portion 632-1 and a second portion 632-2 each extending in a perpendicular direction from each other. Electrical contact 600 may be positioned in a respective opening 604 in a manner, such that, when the electrical contact is in an uncompressed state, first portions of the distal ends of the contact portions may be inside the opening, e.g. between the top and bottom surfaces of the housing, while second portions of the distal ends may be outside the opening (e.g., extending above the top surface or below the bottom surface) of the housing.

With reference to FIG. 6B, a configuration of interposer 650 shows electrical contact 600 inside a respective housing of the interposer 650. When the electrical contact 600 is in an uncompressed state inside the opening of the housing, a first portion 632-1 of the distal end 632 of contact portion 624 and a first portion 634-1 of the distal end 634 of contact portion 626 are positioned between the top surface 640 and the bottom surface 642 of the housing. In this example, that first portion is the distal tip of a beam forming the contact portions 624 and 626.

A second portion 632-2 of the distal end 632 may extend below the bottom surface 642 of the housing and serve as a contact surface to be in electrical contact with a substrate, e.g., 110. A second portion 634-2 of the distal end 634 may extend above the top surface 640 of the housing and serve as a contact surface to be in electrical contact with a substrate, e.g., 108. In this example, the second portions are portions of projections extending from the beams forming the contact portions 624 and 626. The second portions, in this example, are at the ends of the projections. Those second portions may include contact surfaces and may form portions of the mating interfaces of the interposer.

In such configuration, a robust, low profile interposer may be achieved. Though portions of the beams are exposed for mating, the distal tip of each contact portion (e.g., portions 632-1, 634-1) is protected inside the opening of the housing. In contrast to a conventional interposer, in the example robust and low profile interposer described herein, the distal tips of the beams forming the electrical contacts are protected from snagging on a component drawn across the mating interface, such as may occur from unintentional contact with the mating interface of the interposer or misalignment of a component pressed into the mating interface.

For example, with reference to FIG. 6C, the distance between the top and bottom surfaces of the interposer to be small, thus a low profile configuration for the interposers can be achieved. This distance is shown as D1 and may be less than 0.7 mm, 0.6 mm, 0.5 mm, or 0.4 mm, for example. The distance between distal ends of the contact portions of the electrical contacts 600, exclusive of the portions extending beyond the top and bottom surfaces, may be the same as or less than the separation between the top and bottom surfaces. Further, the length of the contact portions (in longitudinal direction L) may be made shorter to achieve a similar compression force (as compared to conventional interposers). As a result, the length of an opening 604 of the housing (shown as W) may be small, for example, less than 1.2 mm, less than 1.1 mm.

With further reference to FIGS. 6A-6C, distal ends 632, 634 of contact portions 624, 626 may be separated from each other in a direction (e.g., z as shown in FIG. 6C) that is perpendicular to the top surface 640 and the bottom surface 642 of the housing. The U-shaped base 622, and the contact portions 624, 626 may be disposed within a plane perpendicular to the top surface 640 and bottom surface 624 of the housing.

Returning to FIGS. 6B and 6C, an interposer housing may have one or more shelves extending into openings (604). The shelves may occupy a sufficient portion of the opening at the bottom surface that an electrical contact inserted from the top will not fall through the bottom surface. Nonetheless, the shelves may leave a sufficient amount of the opening at the bottom surface that the second portion of the distal end of the contact may extend through the bottom surface to form a portion of a mating interface. In this example, a first shelf 628 and a second shelf 630 are formed near the bottom surface.

In some embodiments, the shelves 628, 630 may be molded with the housing. Electrical contact 600 may be positioned on its side on the shelves 628, 630. For example, a side portion 622-1 of the U-shaped base 622 is adjacent shelf 628. Shelf 628 may have a curved surface extending from a wall 618 of the opening. In the configuration shown, the curved surface of the shelf 628 follows the shape of the side portion of the U-shaped base. Additionally, and/or alternatively, a portion of the distal end of contact portion 624 (e.g., 632-1) may be adjacent to shelf 630 of the opening 604. Shelf 630 may have a curved surface that follows the shape of the portion 632-1 of the distal end 632. The electrical contact 600 may be inserted into the opening 604 from the top surface of the housing to rest on shelves 628, 630 without falling out from the bottom surface of the housing.

With reference to FIG. 6C, interposer 650 may include a layer 648 disposed on the top surface 640 of the housing. Layer 648 may extend over the opening 604 and may have an aperture 652 aligned with the portion 634-2 of the distal end of the contact portion 626 to enable portion 634-2 to extend above the top surface 640, to be in electrical contact with a substrate (e.g., 108 in FIG. 1). Layer 648 may be a plastic layer, which may be a film, such as a polyimide film.

With reference to FIG. 6B, in some embodiments, a process for fabricating interposer 650 may include inserting electrical contact 600 into a respective opening 604 of a housing, such that a portion (e.g., 632-2) of a distal end of the contact portion 624 of the electrical contact extends below the bottom surface 642 of the housing, and a portion (e.g., 634-2) of a distal end of the contact portion 626 of the electrical contact extends above the top surface 640 of the housing. While inserted in the opening, another portion (e.g., 632-1) of the distal end of contact portion 624 and another portion (e.g., 634-1) of the distal end of contact portion 626 may be inside the opening between the top and bottom surfaces of the housing. In this example, the portion of the distal end inside the opening is the distal tip.

In some embodiments, electrical contact 600 may be inserted in the opening from the top surface 640 of the housing, where shelves 628, 630 are positioned in the opening near the bottom surface 642 of the housing. Thus, inserting the electrical contact 600 may include positioning the electrical contact on its side on shelves 628, 630 in the opening. For example, a side portion of the base (e.g., 622-1) of the electrical contact may be adjacent to and rest on shelf 628. Portion 632-1 of the distal end of contact portion 624 may be adjacent to and rest on shelf 630. The curved surface of shelf 628 may follow the shape of the portion 622-1 of the U-shaped base, to enable the electrical contact to fit into the opening of the interposer. As shown in FIGS. 6B-6C, when electrical contact is inserted in the opening, shelves 628, 630 block the electrical contact 600 from falling out from the bottom surface of the housing.

With reference to FIG. 6C, the fabrication process may further apply a layer 648 on the top surface 640 of the housing to extend over the opening while aligning an aperture 652 of the layer with portion 634-2 of the distal end of the contact portion 626. The aperture 652 enables the portion 634-2 to extend above the layer 648. As a result, electrical contact 600 is captured between layer 648 and shelf 628/630 and sealed inside the opening, with portions 632-2, 634-2 of distal ends of contact portions extending outside the opening for contacting respective substrates (e.g., 108, 110 of FIG. 1) in an application environment. Aperture 652 in the layer enables the portion 634-2 of the distal end of contact portion 626 to freely move about the top surface 640 when the electrical contact is compressed and/or uncompressed. The portion 632-2 of the distal end of the other contact portion 624 may also freely move about the bottom surface 642 when the electrical contact is compressed and/or uncompressed.

Layer 648 may be any suitable layer that can be bound to the top surface. For example, layer 648 may be a plastic layer, which can be applied to the top surface 640 of the housing by adhesive. In another example, layer 648 may be a heat-activated film such that the layer is bonded to the insulative housing through application of heat. After applying layer 648 to the top surface 640 of the housing during the fabrication process, heat may be applied to layer 648 to activate the same to bond it to the housing.

Although electrical contact 600 is described in FIGS. 6A-6C as a single contact, it is appreciated that an array of multiple electrical contacts 600 may be arranged and stamped from a conductive metal, in a similar manner as described in embodiments of FIGS. 2-5C. For example, a plurality of electrical contacts 600 may be stamped from a conductive metal sheet with or without a supporting strip. Similar to the arrangement shown in FIG. 3A, the plurality of electrical contacts may also be arranged at an angle to achieve spacing saving. For example, in the various embodiments described above, where the longitudinal length of each opening may be achievable at less than 1.1 mm, e.g., 0.81 mm to 1.06 mm, a tight spacing (small pitch), e.g., less than 0.7 mm×0.7 mm, or 0.65 mm×0.65 mm may be achieved.

The plurality of electrical contracts 600 may be aligned to respective openings of a plurality of openings in a housing using a supporting strip and severed from the supporting strip before or while being inserted into the respective opening. Subsequently, a layer (e.g., 648 in FIG. 6C) may be applied to the surface of the housing to extend over the plurality of openings, where the layer includes a plurality of apertures respectively aligned with a plurality of openings of the housing, where each aperture enables a portion of the distal end of a contact portion of a respective electrical contact to extend through the layer for contacting with a substrate.

Having thus described several embodiments, it is to be appreciated various alterations, modifications, and improvements may readily occur to those skilled in the art. Such alterations, modifications, and improvements are intended to be within the spirit and scope of the invention.

It is shown in the various embodiments above that each electrical contact in a respective opening of the housing has two contact portions each having a contact portion that includes a beam extending through the top or bottom surfaces of the housing of the interposer. This configuration provides a dual-compression design. As another example of a possible variation, one of the contact portions of the electrical contact may not need to have an extended beam. For example, the two contact portions of an electrical contact may have different types of structure, with the first contact portion having an extended beam as described above and the second contact portion using a different contact mechanism. For example, the second contact portion may include a solder ball, which may lead to an interposer with one separable interface and a fixed interface which may enable the interposer to be soldered to a substrate.

As described above, the support strip or carrier may be used to align multiple electrical contacts to respective openings of a housing simultaneously. As yet another example of a possible variation, any number of electrical contacts (e.g., one or more) may be inserted into one or more respective openings. The electrical contacts to be used with a single carrier may not be limited to any number or any particular arrangement. This provides flexibility in manufacturing an interposer with any number of electrical contacts. In other variations, different electrical contacts may be inserted to the same housing at different times. For example, multiple electrical contacts may be inserted and locked into a first row of openings in the housing of an interposer, followed by another group of electrical contacts being inserted and locked into a second row of openings.

As described above with reference to FIG. 4A, the carrier (e.g., support strip) may be used to align multiple electrical contacts to respective openings of a housing simultaneously. As yet another example of a possible variation, any number of electrical contacts (e.g., one or more) may be inserted into one or more respective openings. The electrical contacts to be used with a single carrier may not be limited to any number or any particular arrangement. This provides flexibility in manufacturing an interposer with any number of electrical contacts. In other variations, different electrical contacts may be inserted to the same housing at different times. For example, multiple electrical contacts may be inserted and locked into a first row of openings in the housing of an interposer, followed by another group of electrical contacts being inserted and locked into a second row of openings.

As an example of another variation, FIG. 1 illustrates an interposer used to connect two printed circuit boards mounted in parallel. In other examples, an interposer as described herein may be used for other purposes. For example, an interposer as described herein may be used in a chip socket. In such a configuration, the contact points of a separable interface of the interposer may be arranged to align with pads on a surface of a semiconductor chip and the interposer may be used in connection with mechanical components that press the semiconductor chip against the separable interface. Alternatively, an interposer as described herein may be used as part of a cable termination. In such a configuration, the contact points of a separable interface of the interposer may be arranged to align with pads on a surface of a flat flexible cable (FFC) or a paddle card to which one or more cables are terminated.

As an example of another variation, FIG. 2 illustrates an interposer with parallel columns of electrical contacts, with each column having the same pattern of contacts. The columns are aligned such that the contacts form a square array. In other examples, some of the columns may have different patterns of contacts of adjacent columns may be shifted such that electrical contacts in one column are aligned with the space between contacts in adjacent columns.

Further, FIG. 2 illustrates an interposer with an array of electrical contacts organized in rows or columns. The contacts have elongated directions that make an acute angle with respect to the column direction. In a variation, an array with contacts may have an elongated direction that is perpendicular to the column direction.

As an example of another possible variation, FIG. 3C illustrates an electrical contact with contact portions having distal tips bent back towards a central plane of the interposer such that the distal tips of the contact portions extend into the opening in the interposer housing, even when the electrical contact is in an uncompressed state. In a variation, electrical contacts may have some or all of the distal tips outside of the housing in an uncompressed state.

As an example of another possible variation, FIGS. 6B-6C illustrate shelves (e.g., 628, 630) molded with the housing to enable the electrical contact being inserted in the opening and stay inside the opening, followed by applying a layer to seal the opening. In a variation, the interposer may not have the shelves in the opening. The interposer may include two layers disposed on the top and bottom surfaces of the housing, respectively. The manufacturing process may include applying a first layer to seal the opening(s) of the housing on one side, inserting the electrical contact(s) from the other side of the housing, and applying a second layer to seal the opening(s) of the housing completely, keeping the electrical contact(s) secured in the respective openings.

Variations of embodiments are described in this disclosure, which include, but are not limited to, the following examples:

A1. An interposer, comprising: an insulative housing comprising: (1) a top surface and a bottom surface parallel to the top surface; and (2) a plurality of openings extending between the top surface and the bottom surface; and a plurality of electrical contacts, each disposed within a respective opening of the plurality of openings and comprising a base, a first beam extending from the base and comprising a distal end, a second beam extending from the base and comprising a distal end, wherein, for each of the plurality of electrical contacts, when the electrical contact is in an uncompressed state: (1) a first portion of the distal end of the first beam and a first portion of the distal end of the second beam are positioned between the top surface and the bottom surface; and (2) a second portion of the distal end of the first beam extends above the top surface and a second portion of the distal end of the second beam extends below the bottom surface.

A2. The interposer of example A1, wherein the base is U-shaped.

A3. The interposer of example A1, wherein the distal end of the first beam and the distal end of the second beam extend away from each other in a direction perpendicular to the top surface and the bottom surface.

A4. The interposer of example A1, wherein for each of the plurality of electrical contacts, the base, the first beam and the second beam are integral.

A5. The interposer of example A4, wherein for each of the plurality of electrical contacts: the base is disposed in a plane parallel to the top surface and the bottom surface; the first beam of the electrical contact is bent from a first portion of the base of the electrical contact away from the plane in a first direction; and the second beam of the electrical contact is bent from a second portion of the base of the electrical contact away from the plane in a second direction, opposite the first direction.

A6. The interposer of example A5, wherein each of the plurality of openings comprises a shelf parallel to the top surface and the bottom surface, and wherein, for each of the plurality of electrical contacts, the base abuts the shelf in a respective opening of the plurality of openings.

A7. The interposer of example A5, wherein for each of the plurality of electrical contacts the base is U-shaped and a spacing within the plane between the distal end of the first beam and the distal end of the second beam of the electrical contact is smaller than a spacing between the first portion of the U-shaped base and the second portion of the U-shaped base.

A8. The interposer of example A1, wherein for each of the plurality of electrical contacts, a distal tip of the first beam curves towards the bottom surface and a distal tip of the second beam curves towards the top surface, whereby the distal tips of the first beam and the second beam are protected inside the respective opening of the insulative housing.

A9. The interposer of example A3, wherein for each of the plurality of electrical contacts: the base, the first beam and the second beam of the electrical contact are disposed within a plane perpendicular to the top surface and the bottom surface.

A10. The interposer of example A9, wherein: each of the plurality of openings comprises a respective first shelf; and for each of the plurality of electrical contacts: a side portion of the base abuts the first shelf in a respective opening.

A11. The interposer of example A10, wherein each of the plurality of openings comprises a second shelf, and wherein, for each of the plurality of electrical contacts: the first portion of the distal end of the second beam is adjacent to the second shelf of the respective opening.

A12. The interposer of example A9, further comprising: a layer disposed on the top surface of the insulative housing, the layer extending over the plurality of openings, wherein the layer comprises a plurality of apertures respectively aligned with the second portion of the distal end of the first beam of a corresponding electrical contact of the plurality of electrical contacts such that the second portion of the distal end of the first beam of the corresponding electrical contact extends above the top surface.

A13. The interposer of example A12, wherein the layer comprises a plastic film.

A14. The interposer of example A1, wherein for each of the plurality of electrical contacts: the first portion of the distal end of the first beam comprises a distal tip of the first beam; the second portion of the distal end of the first beam comprises a portion of a projection from the distal end of the first beam extending through the top surface; the first portion of the distal end of the second beam comprises a distal tip of the second beam; and the second portion of the distal end of the second beam comprises a portion of a projection from the distal end of the second beam extending through the bottom surface.

A15. The interposer of example A14, further comprising a film over the top surface wherein the projections from the distal ends of the first beams extend through the film.

A16. The interposer of example A15, wherein: the insulative housing comprises a plurality of shelves adjacent the bottom surface within each of the plurality of openings; and for each of the plurality of electrical contacts: (1) the base and the first portion of the distal end of the second beam each abut a shelf within the respective opening; and (2) the second portion of the distal end of the second beam extends through the bottom surface.

A17. The interposer of example A1, wherein a spacing between the top surface and the bottom surface is 0.4 mm or less.

A18. The interposer of example A1, wherein an elongated spacing of each of the plurality of openings is in a range of 0.81 mm to 1.06 mm.

A19. The interposer of example A1, wherein each of the first beam and the second beam of the electrical contact is tapered.

B1. A method of manufacturing an interposer comprising a plurality of electrical contacts held within an insulative member comprising a top surface and a bottom surface parallel to the top surface separated by a first distance, wherein the insulative member comprises a plurality of openings between the top surface and the bottom surface, and the electrical contacts each comprises a base, a first contact portion extending from the base and a second contact portion extending from the base, the method comprising: (1) for each of the plurality of electrical contacts: bending the first contact portion and the second contact portion away from a plane encompassing the base in opposite directions such that a distal end of the first contact portion and a distal end of the second contact portion are separated in a direction perpendicular to the plane; and forming the distal end of the first contact portion and the distal end of the second contact portion into curved portions comprising contact surfaces separated by greater than the first distance and distal tips separated by less than the first distance; (2) inserting the plurality of electrical contacts into respective openings in the insulative member; and (3) locking the electrical contacts within the respective openings.

B2. The method of example B1, wherein locking the respective electrical contact comprises deforming the insulative member adjacent each of the respective openings to form a protuberance that locks the respective electrical contact between the protuberance and a shelf.

B3. The method of example B2, wherein deforming the insulative member comprises heat staking.

B4. The method of example B1, wherein inserting the plurality of electrical contacts into the respective openings in the insulative member comprises: aligning the plurality of electrical contacts with the respective openings in the insulative member, wherein the plurality of electrical contacts are integral with a carrier; severing the plurality of electrical contacts from the carrier; and pressing the plurality of electrical contacts into the respective openings in the insulative member.

B5. The method of example B4, further comprising: stamping the plurality of electrical contacts and the carrier from a sheet of conductive metal.

B6. The method of example B5, wherein stamping the plurality of electrical contacts comprises stamping the first contact portion and the second contact portion of each of the plurality of electrical contacts with a taper.

B7. The method of example B4, wherein inserting the plurality of electrical contacts into the respective openings in the insulative member further comprises, for each of the plurality of electrical contacts: pressing the electrical contact into the respective opening with an assembly tool; and engaging an extension of the electrical contact with a groove of the respective opening such that the electrical contact stays in the respective opening when the assembly tool is withdrawn.

B8. The method of example B1, wherein, for each of the plurality of electrical contacts, when inserted in the respective opening: a second portion of the distal end of the first contact portion extends above the top surface of the insulative member; and a second portion of the distal end of the second contact portion extends below the bottom surface of the insulative member.

C1. A method of manufacturing an interposer comprising a plurality of electrical contacts held within an insulative member comprising a top surface and a bottom surface parallel to the top surface and comprising a plurality of openings between the top surface and the bottom surface, wherein the plurality of electrical contacts each comprises a base, a first contact portion extending from the base and a second contact portion extending from the base, the method comprising: (1) inserting the plurality of electrical contacts into respective openings in the insulative member such that, for each of the plurality of electrical contacts: a first portion of a distal end of the first contact portion extends above the top surface and a first portion of a distal end of the second contact portion extends below the bottom surface; and (2) applying a layer on the top surface of the insulative member and extending over the plurality of openings, wherein the layer comprises a plurality of apertures each aligning with the first portion of the distal end of the first contact portion of a respective one of the plurality of electrical contacts such that the first portion of the distal end of the first contact portion of the respective electrical contact extends above the layer.

C2. The method of example C1, wherein: inserting the plurality of electrical contacts into the respective openings in the insulative member comprises positioning the base of the electrical contacts adjacent shelves within the respective openings.

C3. The method of example C2, wherein: applying the layer on the top surface of the insulative member captures the plurality of electrical contacts between the layer and the shelves within the respective openings.

C4. The method of example C2, wherein inserting the plurality of electrical contacts into respective openings in the insulative member comprises, for each of the plurality of electrical contacts: positioning a side portion of the base on to the shelf of the respective opening, wherein the shelf comprises a curved surface extending from a wall of the respective opening to follow a shape of the side portion of the base.

C5. The method of example C4, wherein the base of each of the plurality of electrical contacts is of a U-shape.

C6. The method of example C2, wherein the first self and the second shelf of each of the plurality of openings are integral with the insulative member.

C7. The method of example C1, wherein the layer is a plastic layer.

C8. The method of example C1, wherein the layer is a polyimide film.

C9. The method of example C1, further comprising tapering the first and second contact portions of each of the plurality of electrical contacts.

Terms signifying direction, such as “top,” “bottom,” “up,” “down,” “upwards” and “downwards,” were used in connection with some embodiments. These terms were used to signify direction based on the orientation of components illustrated or connection to another component, such as a surface of a printed circuit board to which a termination assembly is mounted. It should be understood that electronic components may be used in any suitable orientation. Accordingly, terms of direction should be understood to be relative, rather than fixed to a coordinate system perceived as unchanging, such as the earth's surface.

Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

Also, the phraseology and terminology used herein are for the purpose of description and should not be regarded as limiting. The use of “including,” “comprising,” “having,” “containing,” or “involving,” and variations thereof herein, is meant to encompass the items listed thereafter (or equivalents thereof) and/or as additional items.

What is claimed is:

1. An interposer, comprising:
an insulative housing comprising:
a top surface and a bottom surface parallel to the top surface; and
a plurality of openings extending between the top surface and the bottom surface; and
a plurality of electrical contacts, each disposed within a respective opening of the plurality of openings and comprising a base, a first beam extending from the base and comprising a distal end, a second beam extending from the base and comprising a distal end, wherein, for each of the plurality of electrical contacts, when the electrical contact is in an uncompressed state:
a first portion of the distal end of the first beam and a first portion of the distal end of the second beam are positioned between the top surface and the bottom surface; and
a second portion of the distal end of the first beam extends above the top surface and a second portion of the distal end of the second beam extends below the bottom surface.

2. The interposer of claim 1, wherein the distal end of the first beam and the distal end of the second beam extend away from each other in a direction perpendicular to the top surface and the bottom surface.

3. The interposer of claim 1, wherein for each of the plurality of electrical contacts, the base, the first beam and the second beam are integral.

4. The interposer of claim 3, wherein for each of the plurality of electrical contacts:
the base is disposed in a plane parallel to the top surface and the bottom surface;
the first beam of the electrical contact is bent from a first portion of the base of the electrical contact away from the plane in a first direction; and
the second beam of the electrical contact is bent from a second portion of the base of the electrical contact away from the plane in a second direction, opposite the first direction.

5. The interposer of claim 4, wherein each of the plurality of openings comprises a shelf parallel to the top surface and the bottom surface, and wherein, for each of the plurality of electrical contacts, the base abuts the shelf in a respective opening of the plurality of openings.

6. The interposer of claim 4, wherein for each of the plurality of electrical contacts the base is U-shaped and a spacing within the plane between the distal end of the first beam and the distal end of the second beam of the electrical contact is smaller than a spacing between the first portion of the U-shaped base and the second portion of the U-shaped base.

7. The interposer of claim 1, wherein for each of the plurality of electrical contacts, a distal tip of the first beam curves towards the bottom surface and a distal tip of the second beam curves towards the top surface, whereby the distal tips of the first beam and the second beam are protected inside the respective opening of the insulative housing.

8. The interposer of claim 2, wherein for each of the plurality of electrical contacts:
the base, the first beam and the second beam of the electrical contact are disposed within a plane perpendicular to the top surface and the bottom surface.

9. The interposer of claim 1, wherein a spacing between the top surface and the bottom surface is 0.4 mm or less.

10. The interposer of claim 1, wherein an elongated spacing of each of the plurality of openings is in a range of 0.81 mm to 1.06 mm.

11. The interposer of claim 1, wherein each of the first beam and the second beam of the electrical contact is tapered.

12. A method of manufacturing an interposer comprising a plurality of electrical contacts held within an insulative member comprising a top surface and a bottom surface parallel to the top surface separated by a first distance, wherein the insulative member comprises a plurality of openings between the top surface and the bottom surface, and the electrical contacts each comprises a base, a first contact portion extending from the base and a second contact portion extending from the base, the method comprising:
for each of the plurality of electrical contacts:
bending the first contact portion and the second contact portion away from a plane encompassing the base in opposite directions such that a distal end of the first contact portion and a distal end of the second contact portion are separated in a direction perpendicular to the plane; and
forming the distal end of the first contact portion and the distal end of the second contact portion into curved portions comprising contact surfaces separated by greater than the first distance and distal tips separated by less than the first distance;
inserting the plurality of electrical contacts into respective openings in the insulative member; and
locking the electrical contacts within the respective openings.

13. The method of claim 12, wherein locking the respective electrical contact comprises deforming the insulative member adjacent each of the respective openings to form a protuberance that locks the respective electrical contact between the protuberance and a shelf.

14. The method of claim 13, wherein deforming the insulative member comprises heat staking.

15. The method of claim 12, wherein inserting the plurality of electrical contacts into the respective openings in the insulative member comprises:
aligning the plurality of electrical contacts with the respective openings in the insulative member, wherein the plurality of electrical contacts are integral with a carrier;
severing the plurality of electrical contacts from the carrier; and
pressing the plurality of electrical contacts into the respective openings in the insulative member.

16. The method of claim 15, further comprising:
stamping the plurality of electrical contacts and the carrier from a sheet of conductive metal.

17. The method of claim 16, wherein stamping the plurality of electrical contacts comprises stamping the first contact portion and the second contact portion of each of the plurality of electrical contacts with a taper.

18. The method of claim 15, wherein inserting the plurality of electrical contacts into the respective openings in the insulative member further comprises, for each of the plurality of electrical contacts:
pressing the electrical contact into the respective opening with an assembly tool; and
engaging an extension of the electrical contact with a groove of the respective opening such that the electrical contact stays in the respective opening when the assembly tool is withdrawn.

19. The method of claim 12, wherein, for each of the plurality of electrical contacts, when inserted in the respective opening:
a second portion of the distal end of the first contact portion extends above the top surface of the insulative member; and
a second portion of the distal end of the second contact portion extends below the bottom surface of the insulative member.

20. A method of manufacturing an interposer comprising a plurality of electrical contacts held within an insulative member comprising a top surface and a bottom surface parallel to the top surface and comprising a plurality of openings between the top surface and the bottom surface, wherein the plurality of electrical contacts each comprises a base, a first contact portion extending from the base and a second contact portion extending from the base, the method comprising:
inserting the plurality of electrical contacts into respective openings in the insulative member such that, for each of the plurality of electrical contacts,
a first portion of a distal end of the first contact portion extends above the top surface and a first portion of a distal end of the second contact portion extends below the bottom surface; and
applying a layer on the top surface of the insulative member and extending over the plurality of openings, wherein the layer comprises a plurality of apertures each aligning with the first portion of the distal end of the first contact portion of a respective one of the plurality of electrical contacts such that the first portion of the distal end of the first contact portion of the respective electrical contact extends above the layer.
